(19) United States
(12) Patent Application Publication
(10) Pub. No.: US 2026/0012161 A1
(43) Pub. Date: Jan. 8, 2026

(54) Energy Recovery Adiabatic Flip-Flop and Resonator Based Bennett Clock Generator

(71) Applicants: Indiana Integrated Circuits, LLC, South Bend, IN (US); University of Notre Dame du Lac, Notre Dame, IN (US)

(72) Inventors: Gregory Snider, Niles, MI (US); Rene Celis-Cordova, Hilsboro, OR (US); Alexei Orlov, South Bend, IN (US); Tian Lu, Osceola, IN (US); Jason M. Kulick, South Bend, IN (US)

(21) Appl. No.: 18/875,205

(22) PCT Filed: Jun. 21, 2023
(86) PCT No.: PCT/US23/25854

§ 371 Date: Dec. 16, 2024

Related U.S. Application Data
(60) Provisional application No. 63/354,109, filed on Jun. 21, 2022.

(51) Int. Cl. H03K 3/037

(52) U.S. Cl. CPC H03K 3/037

(57) ABSTRACT

A method including, during time period A, in a computer storage element having first and second power inputs separated by an array of transistors configured for storing a computer bit of data, moving an input of the array of transistors a logic value “1” or “0” a master latch, during time period B, recovering at least a portion of energy comprising the input with a first clock, during a time period C, moving the input in the master latch to an isolation stage, during time period D, recovering at least a portion of energy comprising the input from the isolation stage with a second clock, during time period E, recovering at least a portion of energy comprising the input from a follower latch with a third clock, and during time period F, moving at least a portion of the input from the isolation stage to the follower latch.

### CROSS-REFERENCE TO RELATED APPLICATION

This application claims the benefit of U.S. Provisional Patent Application No. 63/354,109, filed Jun. 21, 2022, the disclosure of which is incorporated herein by reference.

### BACKGROUND OF THE INVENTION

Despite the exponential progress over the past fifty years the increase of performance of computing devices is coming to an end. Modern microprocessors are limited by heat generation, and their speeds have been capped at 4 GHZ since 2004. Traditional Complementary MOSFET logic (CMOS) circuits dissipate energy every time they switch in the form of heat.

Accordingly, those skilled in the art continue research and development in the field of energy recovery for computing devices.

### SUMMARY

Generally, provided, in some non-limiting embodiments or examples, is a computer storage element and method of use thereof. In some non-limiting embodiments, the computer storage element may be a flip-flop or memory. In some non-limiting embodiments, the computer storage element may be operated in a manner that reduces, minimizes, or avoids electrical power from entering the computer storage element and thereby power consumption and, hence, heat generation in the computer storage element over prior methods of use.

In one example, the disclosed method includes during a time period A, in a computer storage element having first and second power inputs separated by an array of transistors of the computer storage element configured for storing a computer bit of data, moving an input of the array of transistors a logic value “1” or “0” to a master latch, during a time period B, after time period A, recovering at least a portion of energy comprising the input with a first clock, during a time period C, after time period B, moving the input in the master latch to an isolation stage, during a time period D, after time period C, recovering at least a portion of energy comprising the input from the isolation stage with a second clock, during a time period E, after time period D, recovering at least a portion of energy comprising the input from a follower latch with a third clock, and during a time period F, after time period E, moving at least a portion of the input from the isolation stage to the follower latch.

### BRIEF DESCRIPTION OF THE DRAWINGS

The disclosure will be described with reference to the following drawing figures wherein like reference numbers identify like parts throughout.

FIG. 1A is a schematic drawing of a traditional CMOS inverter;

FIG. 1B is a timing diagram for the CMOS inverter of FIG. 1A;

FIG. 2A is a schematic drawing of an Adiabatic inverter implemented with split-rail charge recovery logic (SCRL);

FIG. 2B is a timing diagram for the Adiabatic inverter of FIG. 2A;

FIG. 3A is a schematic drawing of three SCRL inverters connected in series;

FIG. 3B is a timing diagram of Bennett clocking for the three SCRL inverters of FIG. 3A;

FIG. 4A is a schematic drawing of adiabatic SCRL circuits and sequential elements connected in series;

FIG. 4B is a timing diagram for the sequential elements of FIG. 4A;

FIG. 5A is a schematic drawing of an adiabatic master-slave flip-flop in accordance with the principles of the present invention;

FIG. 5B is a timing diagram, in accordance with the principles of the present invention, for the adiabatic master-slave flip-flop of FIG. 5A;

FIG. 6A is a schematic of generation of a Bennett clock pair; and

FIG. 6B is a diagram of FIG. 6B illustrating ramp and hold periods for a single Bennett phase.

### DESCRIPTION OF THE INVENTION

Disclosed herein is methodology and design of flip-flops and SRAM cells that implement adiabatic computing using SCRL logic. The present disclosure utilizes the disclosure of U.S. Pat. No. 11,488,660, the contents of which are incorporated in its entirely herein by reference.

Despite the exponential progress over the past fifty years the increase of performance of computing devices is coming to an end. Modern microprocessors are limited by heat generation, and their speeds have been capped at 4 GHz since 2004. Traditional Complementary MOSFET logic (CMOS) circuits dissipate energy every time they switch in the form of heat. CMOS devices switch using sharp transitions and yield the following equation for their dissipation energy:

$${E}_{CMOS} = \frac{1}{2} {CV}_{DD}^{2} \qquad ( 1 )$$

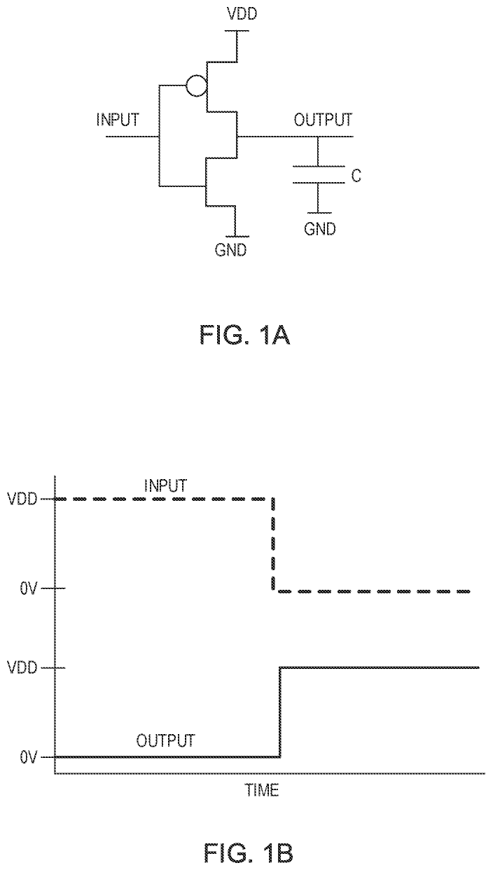

Here, C is the load capacitance of the logic gate, and V_{DD} is the power supply. The energy is discarded and dissipated into heat after each switching event, therefore imposing a speed limit on the operation of modern computing devices. A diagram of a traditional CMOS inverter is presented in FIG. 1(a) and its timing diagram is presented in FIG. 1(b).

Adiabatic reversible computing is a viable alternative to traditional circuit implementations since it reduces heat generation by avoiding unnecessary dissipation. Adiabatic reversible computing, or simply adiabatic computing, uses reversible logic and quasi-adiabatic transitions to reduce heat generation by introducing a trade-off between speed and power. This can be implemented by using a slowly ramping clock as a voltage supply yielding the following expression for energy dissipation:

$${E}_{adiabatic} = {CV}_{t}^{2} \frac{RC}{T} \qquad ( 2 )$$

Here C is the load capacitance of the logic gate, and Vt is the ramping power supply, RC is the intrinsic time constant of the gate, and T is the ramping time of the power supply. The extra term including the RC time constant of the gate and the ramping time of the power supply allows for further reduction in the dissipation energy. When T is much lower than the RC time constant of the gate the dissipation can be reduced considerably.

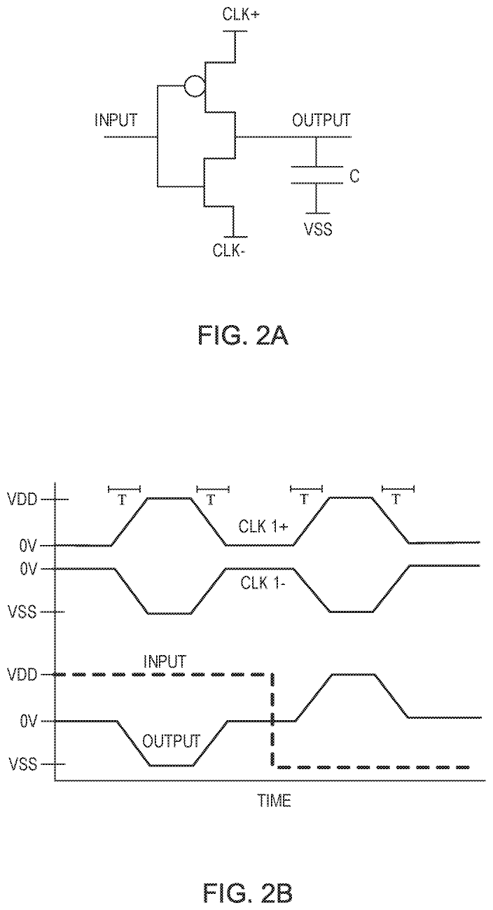

Adiabatic computing can be implemented as split-rail charge recovery logic (SCRL) [1]. An inverter using adiabatic SCRL logic is shown in FIG. 2(a), where the power supply and ground terminals have been replaced by positive and negative ramping clocks with a ramping period T. As seen in FIG. 2(b), both ramping clocks start at a null state (0 V), then ramp up for time T until reaching a valid logic state, retain the logic value for some period, and ramp back down to the null state recovering energy. The energy recovery step is critical to avoid energy dissipation, but information or data (logical ‘1’ or ‘0’) is lost between cycles since the inverter returns to a null state. During the computing stages, the output of the inverter will follow either the positive or the negative clock to represent a logical ‘1’ or a logical ‘0’.

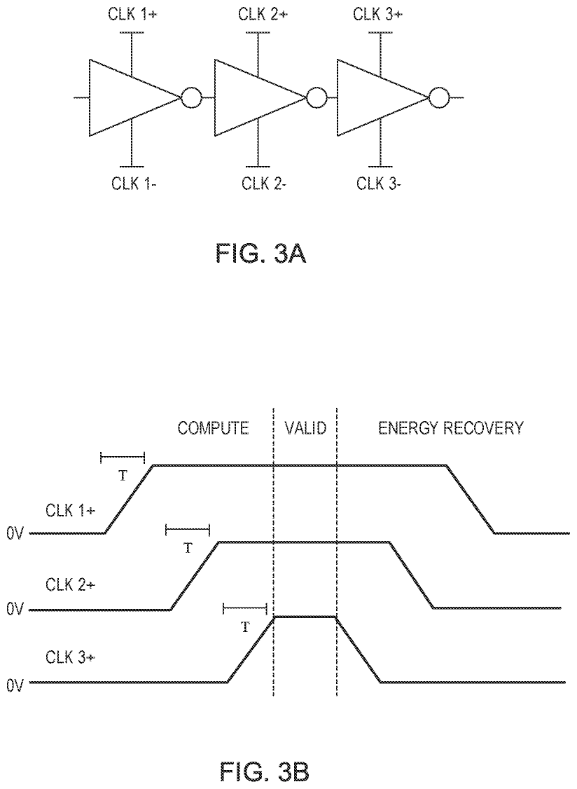

Since the logic values of SCRL gates are not valid when the clocks are ramping up and down, or during the null state, any following gates will require clocks with a different phase. A chain of three SCRL inverters is shown in FIG. 3, which illustrates the use of phased clocks to power different stages of the circuit. This clocking scheme is known as Bennett clocking [2], which consists of clocks that only ramp up once the previous stage has a valid state. Similarly, during the energy recovering process the last level of logic ramps down first, and once the null state is reached the previous stage follows. Bennett clocking ensures that the logical input values of the circuit are valid during the compute and the energy recovery steps, and presents a straightforward implementation to adiabatic computing.

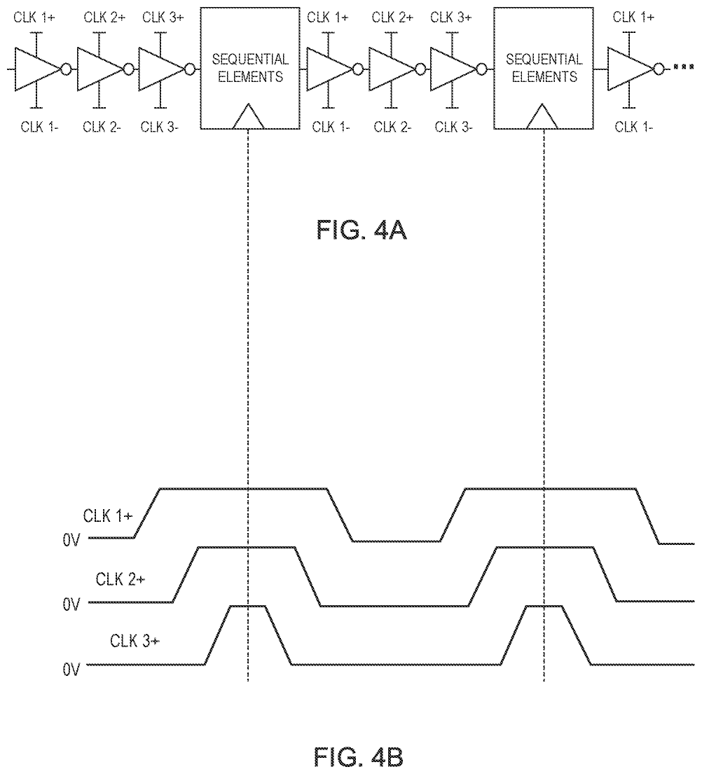

Even though adiabatic microprocessors using SCRL circuits as described above have been successfully implemented [3], sequential elements were not implemented using adiabatic logic. Modern CMOS circuits have both combinational logic, such as the three-inverter chain described above, and sequential logic that consists of memory elements to store the results obtained by the combinational logic. This is illustrated in FIGS. 4(a) and 4(b), which shows that multiple combinational logic blocks can use the same set of Bennett clocks while their intermediate results are stored in sequential elements. The sequential elements are registers comprised of flip flop gates, or memory elements comprised of SRAM cells. These sequential elements will sample the result of the combinational logic during the valid period, when all clocks have ramped up, and will provide the result as an input to the next set of combinational logic at the next cycle.

The adiabatic flip-flop and memory design are the first of its kind and could be used in any practical implementation of adiabatic computing such as adiabatic microprocessors. Adiabatic microprocessors using the proposed cells will fully implement adiabatic computing.

The timing requirements for sequential elements separating Bennett clocked combinational logic is somewhat complicated since the data should be latched in when the Bennett clock phases are all active, but the data should not appear on the latch output until all Bennett phases have ramped back down. This can be accomplished by a master-follower flip-flop with two power clocks and an additional control signal.

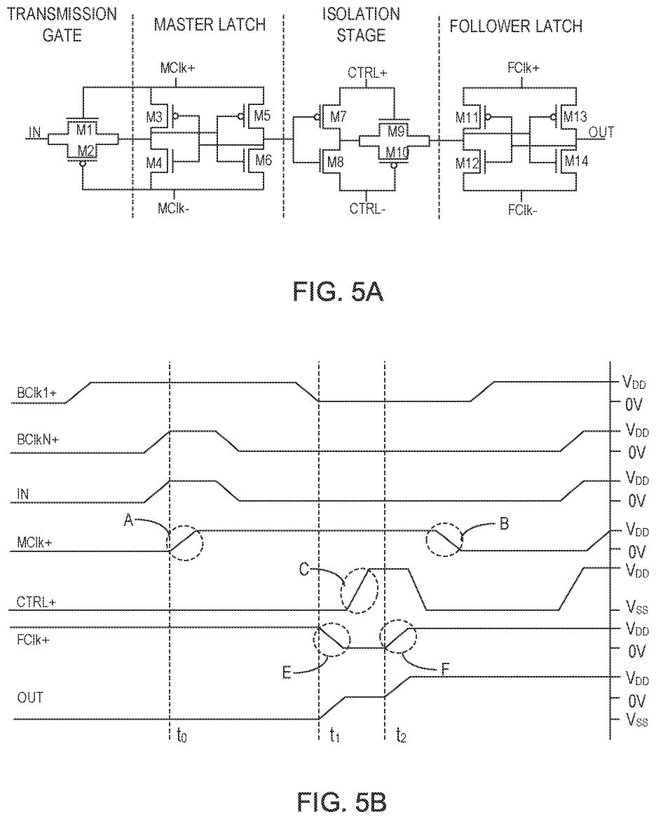

The design of the adiabatic master-follower flip-flop (AMFFF) is presented in FIG. 5(a). The design uses an energy recovery master latch as the master stage, and another energy recovery latch as the follower latch, left-side and right-side, respectively, separated by an energy recovery isolation stage. While there is destruction of data at the latches, necessitating some energy loss, the energy recovering stages helps to minimize the loss.

FIG. 5(b) illustrates an example Bennett clock signals BClk1+ and BClkN+. These Bennett clock signals, BClk1+ and BClkN+, and their inverse (negative) clocks, BClk1−and BClkN− (not shown), may be used with a plurality of unillustrated instances of combinational logic as shown in FIG. 4(a). In an example where there is unillustrated combinational logic that precedes, in series, the illustrated AMFFF shown in FIG. 5(a), the “In” of the illustrated instance of the AMFFF receives a digital input “1” or “0” from the combinational logic.

Still referring to FIG. 5(b), clock signals BClk1+, BClkN+, MClk+, CTRL+, and FClk+, and their respective inverses BClk1−, BClKN−. MClk−, CTRL−, and FClk− (not shown for simplicity), can be generated by an external circuitry that is not shown for the purpose of simplicity. However, it is envisioned that this external circuitry may include logic circuits, resonators (e.g., without limitation, piezoelectric resonators) and/or a microprocessor programmed or configured to provide these clock signals and their respective inverses.

Moreover, in FIG. 5(b), clock signals MClk+, CTRL+, and FClk+, and their respective inverses MClk−, CTRL−, and FClk− (not shown for simplicity), are examples of Bennett clock signals, like BClk1+ and BClkN+, and their inverse (negative) clocks, BClk1− and BClkN−, but are described and designated herein as clock signals MClk+, CTRL+, and FClk+, and their respective inverses MClk−, CTRL−, and FClk−, for the purpose of describing the present invention.

FIG. 5(a) illustrates one non-limiting example of an AMFFF that includes 14 transistors. However, this is not to be construed in a limiting sense since it is envisioned that, in practice, an AMFFF may include more or less transistors as may be deemed suitable and/or desirable by one skilled in the art for a particular application or function. Accordingly, the AMFFF shown in FIG. 5(a) is not to be construed as limiting the present invention.

In the example AMFFF shown in FIG. 5(a), transistors M2, M3, M5, M7, M10. M11 and M13 are p-channel MOSFETs; while the transistors M1, M4, M6, M8, M9, M12, and M14 are n-channel MOSFETs. The input “In” is passed through a transmission gate that includes, in an example, transistors M1 and M2, which are controlled by the positive and negative master clock signals (MClk+ and MClk−). In an example, transistors M3, M4, M5 and M6 form a master latch which, under the control of master clock signals MClk+ and MClk−during a time period A in FIG. 5(b), latches data (logical ‘1’ or ‘0’) present in the input IN of the transmission gate into the master latch while the Bennett clocks are at V_{DD} (for BClk1+ and BClkN+) and VSS (not shown, for BClk1− and BClkN−). Moreover, the transistors of the master latch under the control of master clock signals MClk+ and MClk−, during a time period B in FIG. 5(b) which follows time t2, perform partial energy recovery of any data retained in the master latch while the Bennett clocks, BClk1+, BClkN+, BClk1− and BClkN−, are in their null states, e.g., 0 Volts.

In an example, each of BClk1+ and BClkN+switch between a null logic state represented, for example, by 0 Volts (e.g., don't care) and V_{DD} while each of BClk1− and BClkN− (the inverses of BClk1+ and BClkN+) switch (at the same time as BClk1+ and BClkN+) between a null logic state represented, for example, by 0 Volts (e.g., don't care) and VSS (not specifically shown for BClk1− and BClkN−).

In an example, each of clock signals MClk+ and FClk+switch between a null logic state represented, for example, by 0 Volts (e.g., don't care) and V_{DD} while each of clock signals MClk− and FClk−(the inverses of clock signals MClk+ and FClk+) switch (at the same time as clock signals MClk+ and FClk+) between a null logic state represented, for example, by 0 Volts (e.g., don't care) and VSS (not specifically shown for clock signals MClk− and FClk).

Finally, in an example, control signal CTRL+switches between VSS and V_{DD} (as shown in FIG. 5(b)), while control signal CTRL− (not specifically shown; the inverse of control signal CTRL+) switches (at the same time as control signal CTRL+) between V_{DD} and VSS. In an example, V_{DD} may be a positive voltage while VSS may be a negative voltage. However, this is not to be construed in a limiting sense since it is envisioned that each of V_{DD} and VSS may be any suitable and/or desirable voltage that facilitates the operation of the AMFFF described herein.

Once the Bennett clocks BClk1+, BClkN+, BClk1− and BClkN− are in their null states, e.g., 0 Volts and master clocks MClk+, and MClk− are at respective V_{DD} and VSS (not shown) at time t1, the retained data (logical ‘1’ or ‘0’) in the master latch is moved to the follower latch via transistors M7, M8, M9, and M10 of an isolation stage in response to control signals CTRL+ and CTRL-being activated (from VSS to V_{DD} for control signal CTRL+ and from V_{DD} to VSS for control signal CTRL− (not shown)) during a time period C in FIG. 5(b) between times t1 and t2. Transistors M7, M8, M9 and M10 act as the isolation stage between the master latch and the follower latch.

Once the Bennett clocks BClk1+, BClkN+, BClk1− and BClkN− have been ramped from V_{DD} (for BClk1+ and BClkN+) and from VSS (not shown, for BClk1− and BClkN−) to a null logic state (e.g., don't care), e.g., 0 Volts, the follower clock signals FClk+ and FClk−, beginning at time t1, are ramped during a time period E in FIG. 5(c), from V_{DD} and VSS, respectively, to a null logic state (e.g., don't care), e.g., 0 Volts, partially recovering the energy of any data retained in the follower latch.

As noted above, the isolation stage is activated, during time period C between times t1 and t2, by ramping the control signals CTRL+ from VSS to V_{DD} and CTRL− from V_{DD} to VSS, transferring the data (logical ‘1’ or ‘0’) from the mater latch into the isolation stage. Beginning at time t2, this data is loaded into the follower latch (comprised of transistors M11, M12, M13, and M14) during a time period F in FIG. 5(b) in response to the follower latch clocks FClk+ and FClk− ramping from 0 Volts or null to respective V_{DD} (for FClk+) and VSS (for FClk−). The data (logical ‘1’ or ‘0’) is held in the output (OUT) of the follower latch, ready to be used as an input (IN) in the next Bennett cycle of another circuit (not shown), e.g., combinational logic as in FIG. 4(a)

Thereafter, during a time period D in FIG. 5(b), the control signals CTRL+ and CTRL− ramp from V_{DD} to VSS (for CTRL+) and from VSS to V_{DD} (for CTRL−), thereby recovering energy in the isolation stage and isolating the master latch the follower latch from each other.

In the timing diagram of the AMFFF shown in FIG. 5(b), master clocks MClk+ and MClk− of the master latch are ramped, beginning at time to during time period A in FIG. 5(b), from 0 Volts to V_{DD} (for MClk+) and from 0 Volts to VSS (not shown, for MClk−) when all the phases of the Bennett clocks BClk1+, BClkN+, BClk1− and BClkN− have ramped from 0 Volts to V_{DD} (for BClk1+, BClkN+) and from 0 Volts to VSS (not shown, for BClk1− and BClkN−), whereupon the data at the input (IN) is latched into the master latch following the ramps of master clocks MClk+ and MClk− during time period A that begin at time to.

The master clocks MClk+ and MClk− are then held active, at V_{DD} and VSS respectively, until the Bennett phases, BClk1+, BClkN+, BClk1− and BClkN− have all ramped back from V_{DD} and VSS to 0 Volts or a null state. At this point, labeled time t1, the follower clocks FClk+ and FClk− ramp, during time period E in FIG. 5(b), from respective V_{DD} and VSS to 0 Volts or a null state thereby partially recovering the energy of any data retained in the follower latch.

Thereafter, between times t1 and t2, during time period C in FIG. 5(b), the control signals CTRL+ and CTRL-ramp from VSS to V_{DD} (for CTRL+) and from V_{DD} to VSS (for CTRL−) to move the data (logical ‘1’ or ‘0’) from the master latch into the isolation stage.

Next, during time period F that begins at time t2 in FIG. 5(b), FClk+ and FClk− ramp from 0 Volts or a null state to respective V_{DD} and VSS whereupon the data in the isolation stage is input into the follower latch, whereupon said data is held in the output OUT of the follower latch available as an input (IN) of another circuit (not shown), e.g., another instance of the AMFFF, in the next Bennett cycle thereof.

The current data at the output OUT is retained in the follower latch until the next cycles of MClk+, FClk+, CTRL+, MClk−, FClk−, and CTRL− shown in FIG. 5(b), whereupon the data at the input IN during this next cycle will propagate through the master latch, the isolation stage, and the follower stage to the output OUT thereof in the manner described above.

Herein, for clarity the inverses of the Bennett clocks BClk1 and BClKN, the master and follower clocks MClk and FClk, and the control signal CTRL are omitted from the timing diagram of FIG. 5(b) for clarity.

In this design, energy is partially recovered from the master latch during time period B in FIG. 5(b), the follower latch during time period F in FIG. 5(b), and from the isolation stage during time period D in FIG. 5(b). The amount of energy recovered from each of the master latch, the follower latch, and the isolation stage is limited by the threshold voltage of the transistors forming the master latch, the follower latch, and the isolation stage.

The thus described AMFFF can be used in any sequential element for adiabatic computing such as registers and pipelined microprocessors.

As can be understood from the foregoing, during time periods A-F in FIG. 5(b), the following occurs:
Time Period A: Data (logical ‘1’ or ‘0’) at In of the transmission gate is moved to and stored in the master latch;
Time Period B: Part of the energy comprising the data retained in the master latch is recovered by the circuitry comprising MClk+, MClk−, or both;
Time Period C: Data in the master latch is moved to and stored in the isolation stage;
Time Period D: Part of the energy comprising the data retained in the isolation stage is recovered by the circuitry comprising CTRL+, CTRL−, or both;
Time Period E: Part of the energy comprising the data retained in the follower latch is recovered by the circuitry comprising FClk+, FClk−, or both; and
Time Period F: Data in the isolation stage is moved to and stored in the follower latch, i.e., this data is present at the output (Out) of the follower latch.

Having thus described the operation of the AMFFF shown in FIG. 5(a), a clock circuit to generate a Bennett clock sequence using resonators, in particular, without limitation, piezoelectric contour mode resonators, will now be described. The description herein of resonators being piezoelectric contour mode resonators, however, is not to be construed in a limiting sense since it is envisioned that any suitable and/or desirable resonator that facilitates the generation of Bennett clock sequences in the manner described below may be used.

In Bennett clocking, the power clocks sequentially energize successive levels of logic in the compute phase, and then de-energize logic in the reverse fashion during the de-compute phase, recovering the energy in the circuit. The timing of a three-level, positive going Bennett clock is shown in FIG. 3. To produce the Bennett clocking waveforms of FIG. 3 will require multiple resonators and switching transistors. One non-limiting example is to use a set of four resonators that are phase separated in phase by 90° each.

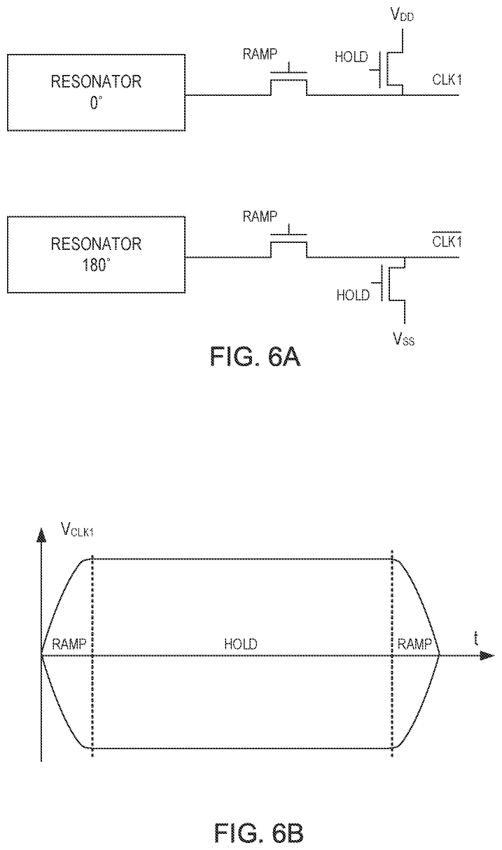

As shown in FIG. 6, each Bennett phase is generated by connecting the appropriate generator or resonator to the output clock line to provide a rising or falling edge at an appropriate time. At the end of a first ramp up (or ramp down) period of time, e.g., ¼ the period of each generator or resonator, the switching transistor (labeled Ramp in FIG. 6) is turned off to disconnect the clock line, and hence the circuitry being driven by the clock signal on the clock line, from the generator or resonator. Depending on the application, an optional second, Hold transistor may be added to the clock line to aid in enforcing a subsequent HOLD period of time.

Without the Ramp transistor isolating the generator or resonator from the circuitry being driven by the clock signal on the clock line, the logic of the circuitry being driven by the generator or resonator is essentially dynamic logic whereupon bit energy are held in load capacitors, i.e., the capacitances of the transistors forming the circuitry being driven by each generator or resonator, for a time limited by the leakage time.

After the HOLD period, the circuitry being driven by each generator or resonator is reconnected by the Ramp transistor to the generator or resonator for a second ramp down (or ramp up) period of time whereupon there will be some irreversible dissipation as the generator or resonator “makes up” the energy that was lost to leakage. However, this energy loss will be comparable to that that which would have been lost by passive leakage during the HOLD time if the clock line were connected to a static power supply.

During the second ramp down (or ramp up) period of time energy is returned to the generator or resonator. Logic technologies that reduce leakage would reduce this energy loss.

If the Hold transistor is added, as shown in FIG. 6(a). This transistor will hold the clock line at V_{DD} or VSS and provide the energy that leaks from the circuitry being driven by the generator or resonator.

Four generators or resonators phased 90° apart are sufficient to implement any number of Bennett phases. These generator or resonators can provide both the positive and negative ramps, using the approach in FIG. 6, required for SCRL. The number of Bennett phases in a practical adiabatic reversible system is likely to be 16 or less, so the amount of time that the bits are dynamically held is not too long for reasonable clock speeds. Controlling the switch transistors will require some logic, but just a simple state machine implemented in conventional CMOS logic and synchronized with the generators or resonators may be used.

The disclosure may be characterized by the following clauses:

Clause 1: A method comprising: during a time period A, in a computer storage element having first and second power inputs separated by an array of transistors of the computer storage element configured for storing a computer bit of data, moving an input of the array of transistors a logic value “1” or “0” to a master latch; during a time period B, after time period A, recovering at least a portion of energy comprising the input with a first clock; during a time period C, after time period B, moving the input in the master latch to an isolation stage; during a time period D, after time period C, recovering at least a portion of energy comprising the input from the isolation stage with a second clock; during a time period E, after time period D, recovering at least a portion of energy comprising the input from a follower latch with a third clock; and during a time period F, after time period E, moving at least a portion of the input from the isolation stage to the follower latch.

Clause 2. The method of clause 1, further comprising, during the time period A, ramping the first clock from a null value to V_{DD}.

Clause 3. The method of any one of clauses 1-2, further comprising, during the time period B, ramping the first clock from VSS to V_{DD}.

Clause 4. The method of any one of clauses 1-3, further comprising, during the time period C, ramping the second clock from VSS to V_{DD}.

Clause 5. The method of any one of clauses 1-4, further comprising, during the time period D, ramping the second clock from V_{DD} to VSS.

Clause 6. The method of any one of clauses 1-5, further comprising, during the time period E, ramping the third clock from V_{DD} to null.

Clause 7. The method of any one of clauses 1-6, further comprising, during the time period F, ramping the third clock from null to V_{DD}.

Although various examples of the disclosed electrochemical device and electrically conductive substrate have been shown and described, modifications may occur to those skilled in the art upon reading the specification. The present application includes such modifications and is limited only by the scope of the claims.

What is claimed is:

1. A method comprising:
during a time period A, in a computer storage element having first and second power inputs separated by an array of transistors of the computer storage element configured for storing a computer bit of data, moving an input of the array of transistors a logic value “1” or “0” to a master latch;
during a time period B, after time period A, recovering at least a portion of energy comprising the input with a first clock;
during a time period C, after time period B, moving the input in the master latch to an isolation stage;
during a time period D, after time period C, recovering at least a portion of energy comprising the input from the isolation stage with a second clock;
during a time period E, after time period D, recovering at least a portion of energy comprising the input from a follower latch with a third clock; and
during a time period F, after time period E, moving at least a portion of the input from the isolation stage to the follower latch.

2. The method of claim 1, further comprising, during the time period A, ramping the first clock from a null value to V_{DD}.

3. The method of claim 1, further comprising, during the time period B, ramping the first clock from VSS to V_{DD}.

4. The method of claim 1, further comprising, during the time period C, ramping the second clock from VSS to V_{DD}.

5. The method of claim 1, further comprising, during the time period D, ramping the second clock from V_{DD} to VSS.

6. The method of claim 1, further comprising, during the time period E, ramping the third clock from V_{DD} to null.

7. The method of claim 1, further comprising, during the time period F, ramping the third clock from null to V_{DD}.
